(19) United States
(12) Patent Application Publication
(10) Pub. No.: US 2021/0264587 A1
(43) Pub. Date: Aug. 26, 2021

(54) FEATURE AMOUNT MEASUREMENT METHOD AND FEATURE AMOUNT MEASUREMENT DEVICE

(71) Applicant: Tokyo Electron Limited, Tokyo (JP)

(72) Inventor: Shinji KOBAYASHI, Koshi City (JP)

(21) Appl. No.: 17/177,938

(22) Filed: Feb. 17, 2021

(30) Foreign Application Priority Data
Feb. 20, 2020 (JP) 2020-027461

(51) Int. Cl. G06T 7/00; G01N 23/2251; G06T 5/00

(52) U.S. Cl. CPC G06T 7/0006; G01N 23/2251; G06T 5/003; G01N 2223/6116; G06T 2207/20076; G01N 2223/418; G01N 2223/507; G06T 2207/10061; G06T 2207/30148; G01N 2223/07

(57) ABSTRACT

A method of measuring a feature amount of a pattern formed on a substrate and provided with periodic irregularities, includes: (A) measuring a pitch of the pattern based on a result of a scanning of a charged particle beam on the substrate; and (B) measuring other feature amounts other than the pitch of the pattern based on the result of the scanning, and correcting the measurement result of the other feature amounts based on a ratio of the measurement result of the pitch obtained in (A) to a design value of the pitch.

### CROSS-REFERENCE TO RELATED APPLICATION

This application is based upon and claims the benefit of priority from Japanese Patent Application No. 2020-027461, filed on Feb. 20, 2020, the entire contents of which are incorporated herein by reference.

### TECHNICAL FIELD

The present disclosure relates to a feature amount measurement method and a feature amount measurement device.

### BACKGROUND

Patent Document 1 discloses a dimension measurement method of measuring the dimensions of a measurement target pattern by scanning the measurement target pattern formed on a sample through the use of a charged particle beam. In this dimension measurement method, the visual field position of the charged particle beam is set so that the measurement position of the measurement target pattern is located between a region where a deposit is deposited by radiating the charged particle beam and a region where the material on the sample is removed by irradiating the charged particle beam, and the dimensions of the measurement target pattern is measured based on the scanning of a set visual field with the charged particle beam.

### PRIOR ART DOCUMENT

### Patent Document

Patent Document 1: Japanese laid-open publication No. 2010-160080

### SUMMARY

According to one embodiment of the present disclosure, there is provided a method of measuring a feature amount of a pattern formed on a substrate and provided with periodic irregularities, includes: (A) measuring a pitch of the pattern based on a result of a scanning of a charged particle beam on the substrate; and (B) measuring other feature amounts other than the pitch of the pattern based on the result of the scanning, and correcting the measurement result of the other feature amounts based on a ratio of the measurement result of the pitch obtained in (A) to a design value of the pitch.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram showing an outline of a configuration of a processing system including a control device as a feature amount measurement device according to a first embodiment.

FIG. 2 is a block diagram showing an outline of a configuration of a controller related to an image processing process and a feature amount calculating process.

FIG. 3 is a diagram showing the brightness of a specific pixel in each of actual frame images.

FIG. 4 is a histogram of the brightness of all the pixels whose X coordinates match a specific pixel of all 256 frames.

FIG. 5 is a flowchart for explaining a process performed in the controller shown in FIG. 3.

FIG. 6 shows an image obtained by averaging frame images of 256 frames.

FIG. 7 shows an artificial image obtained by averaging artificial frame images of 256 frames, which are generated based on the frame images of 256 frames used for image generation in FIG. 6.

FIGS. 8A, 8B and 8C are diagrams showing the frequency analysis results in the artificial images generated from the frame images of 256 frames, and showing a relationship between the frequency and the amount of vibration energy.

FIGS. 9A, 9B and 9C are diagrams showing the frequency analysis results in the artificial images generated from the frame images of 256 frames, and showing a relationship between the number of frames and a noise level of a high frequency component.

FIG. 10 is an image obtained by averaging 256 virtual frame images whose process noise is zero.

FIG. 11 shows an artificial image obtained by generating artificial frame images of 256 frames based on the above-mentioned virtual frame images of 256 frames used for image generation in FIG. 10 and averaging these artificial frame images.

FIGS. 12A, 12B and 12C are diagrams showing the frequency analysis results in the artificial images generated from the 256 virtual frame images whose process noise is zero, and showing a relationship between the frequency and the amount of vibration energy.

FIGS. 13A, 13B and 13C are diagrams showing the frequency analysis results in the artificial images generated from the 256 virtual frame images whose process noise is zero, and showing a relationship between the number of frames and a noise level of a high frequency component.

FIG. 14 is a block diagram showing an outline of a configuration related to an image processing process and a feature amount calculating process in a controller of a control device as a feature amount measurement device according to a second embodiment.

FIG. 15 is a flowchart for explaining a process performed in the controller shown in FIG. 14.

FIG. 16 is a diagram showing an example of images before and after filtering.

FIG. 17 shows an artificial image of an infinite frame generated by a method according to a third embodiment.

FIG. 18 is a block diagram showing an outline of a configuration related to an image processing process and a feature amount calculating process in a controller of a control device as a feature amount measurement device according to a fifth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Inspection and analysis of fine patterns formed on a substrate such as a semiconductor wafer (hereinafter referred to as “wafer”) or the like in a manufacturing process of a semiconductor device are performed through the use of an image (hereinafter referred to as “scanned image”) obtained by scanning a substrate with a charged particle beam such as electron beam or the like. In recent years, it is required to further miniaturize semiconductor devices. Along with this, even higher measurement accuracy is required. Therefore, as a result of diligent investigation conducted by the present inventors, it was found that the pitch of a periodic pattern on a substrate measured from a scanned image may not be constant in the plane of the substrate. The line width of a pattern is changed according to the process conditions at the time of pattern formation. However, if the exposure conditions such as a mask position during exposure and the like are appropriate, the pitch of the pattern is not greatly changed even when other processing conditions at the time of pattern formation are not appropriate. The exposure conditions such as the mask position and the like are strictly controlled. Nevertheless, as described above, the pitch of the pattern measured from the scanned image may not be constant in the plane of the substrate. This means that even if feature amounts other than the pattern pitch (e.g., the line width) are directly calculated based on the scanned image, they may not be accurate.

Therefore, the technique according to the present disclosure accurately measures feature amounts other than the pitch of a pattern based on the result of scanning a substrate, on which a pattern is formed, with a charged particle beam.

Hereinafter, the configuration of a feature amount measurement device according to the present embodiment will be described with reference to the drawings. In the subject specification, elements having substantially the same functional configuration are designated by like reference numerals, and the duplicate description thereof will be omitted.

### First Embodiment

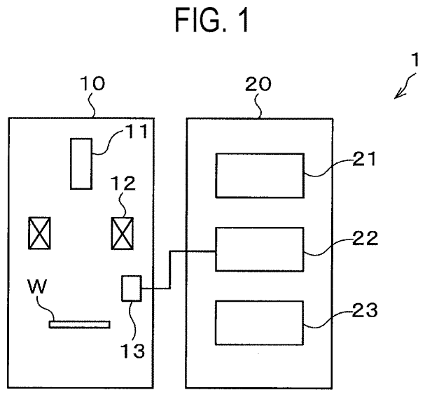

FIG. 1 is a diagram showing an outline of a configuration of a processing system including a control device as a feature amount measurement device according to a first embodiment. A processing system 1 shown in FIG. 1 includes a scanning electron microscope 10 and a control device 20.

The scanning electron microscope 10 includes an electron source 11 that emits an electron beam as a charged particle beam, a deflector 12 for two-dimensionally scanning an imaging region of a wafer W as a substrate with the electron beam emitted from the electron source 11, and a detector 13 that amplifies and detects secondary electrons generated from the wafer W by irradiating the electron beam.

The control device 20 includes a memory part 21 that stores various kinds of information, a controller 22 that controls the scanning electron microscope 10 and controls the control device 20, and a display part 23 that performs various displays.

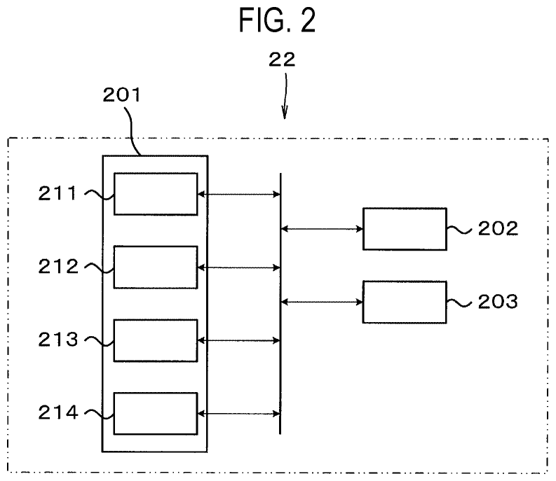

FIG. 2 is a block diagram showing an outline of the configuration of the controller 22 related to an image processing process and a feature amount calculating process. The controller 22 is composed of, for example, a computer equipped with a CPU, a memory and the like, and includes a program storage part (not shown). The program storage part stores programs that control various processes in the controller 22. The programs may be recorded on a non-transitory computer-readable storage medium and may be installed on the controller 22 from the storage medium. A part or all of the programs may be implemented by a dedicated hardware (circuit board). Further, as will be described later, the method of generating a measurement image is not limited. Therefore, a program that causes a measurement image generation part 201 to function, and a program that causes a pitch measurement part 202 and a feature amount measurement part 203 to function, may be provided individually and operated in cooperation with each other.

As shown in FIG. 2, the controller 22 includes the measurement image generation part 201, the pitch measurement part 202 and the feature amount measurement part 203.

The measurement image generation part 201 generates an image (hereinafter referred to as “measurement image”) used for the below-described measurement performed by the pitch measurement part 202 and the feature amount measurement part 203. The measurement image is, for example, an image (hereinafter referred to as “frame integrated image”) obtained by integrating a plurality of frame images or a frame image. However, for the following reasons, in the present embodiment, an image different from the frame integrated image is used as the measurement image. The frame image refers to an image obtained by scanning the wafer W once with an electron beam.

The frame image constituting the frame integrated image contains not only image noise caused by the imaging condition and the imaging environment but also pattern fluctuation caused by the process at the time of pattern formation. As for the image used for analysis or the like, it is important to remove or reduce the image noise, and not to remove the fluctuation as noise, i.e., not to remove a stochastic noise, which is a random variation derived from the process.

In order to reduce the image noise, the number of frames of the frame integrated image may be increased. In other words, the number of times of scanning on the imaging region by the electron beam may be increased. However, if the number of frames is increased, the pattern on the wafer W to be imaged is damaged. In view of this point, the present inventors considered to obtain a measurement image having reduced image noise by artificially creating and averaging a large number of other frame images while suppressing the actual number of frames. In order to artificially create the frame images, it is necessary to determine a method of determining the brightness of pixels in the artificial frame images.

The actual frame image is created based on the result of amplifying and detecting the secondary electrons generated when the wafer W is irradiated with the electron beam. The amount of secondary electrons generated when the wafer W is irradiated with the electron beam follows the Poisson distribution. The amplification factor when amplifying and detecting the secondary electrons is not constant. Further, the amount of secondary electrons generated is also affected by the degree of charge-up of the wafer W and the like. Therefore, it is considered that the brightness of the pixels corresponding to the electron beam irradiation portion in the actual frame image is determined from a certain probability distribution.

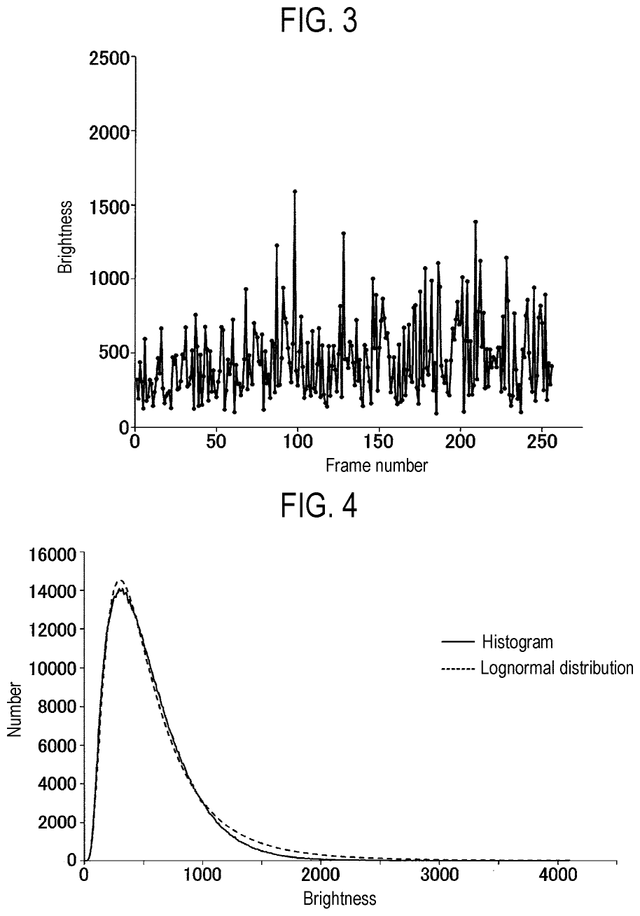

FIGS. 3 and 4 are diagrams showing the results of diligent investigation conducted by the present inventor in order to estimate the aforementioned probability distribution. In this investigation, actual frame images of a wafer on which a line-and-space pattern is formed were prepared as much as 256 frames under the same imaging conditions. FIG. 4 is a diagram showing the brightness of a specific pixel in each of the actual frame images. The specific pixel is one pixel corresponding to the center of a space portion of a pattern, which is considered to have the most stable brightness. FIG. 4 is a histogram of the brightness of all the pixels whose X coordinate matches the specific pixel in all 256 frames. The X coordinate is a coordinate in a direction substantially orthogonal to the extension direction of the line of the pattern on the wafer.

As shown in FIG. 3, in the actual frame image, the brightness of a specific pixel is not constant between frames, and appears to be randomly determined without regularity. The histogram of FIG. 4 follows a lognormal distribution. Based on these results, it is considered that the brightness of the pixel corresponding to the electron beam irradiation portion in the actual frame image is determined from the probability distribution which follows the lognormal distribution.

Based on the above points, in the present embodiment, a plurality of actual frame images of the wafer W is acquired from the same coordinates, and the probability distribution of brightness following the lognormal distribution is determined for each pixel from the acquired plurality of frame images. Then, a random number is generated based on the probability distribution of brightness for each pixel to generate a plurality of other artificial frame images (hereinafter referred to as artificial frame images), and the artificial frame images are averaged to generate an artificial image as a measurement image. According to this method, a large number of artificial frame images can be generated from the actual frame images. Therefore, the image noise in the finally generated artificial image can be reduced as compared with the image obtained by averaging a plurality of actual frame images. Further, it is not necessary to increase the number of times of scanning of the electron beam for obtaining the actual frame image. Therefore, it is possible to reduce image noise while suppressing damage to the pattern on the wafer. Furthermore, in the present embodiment, only the image noise is reduced, and the stochastic noise derived from the process is not removed.

Returning to the description of FIG. 2, the measurement image generation part 201 includes a frame image generation part 211, an acquisition part 212, a probability distribution determination part 213, and an artificial image generation part 214 as an image generation part.

The frame image generation part 211 sequentially generates a plurality of frame images based on the detection result of the detector 13 of the scanning electron microscope 10. The frame image generation part 211 generates frame images of a specified number of frames (e.g., 32 frames). In addition, the generated frame images are sequentially stored in the memory part 21.

The acquisition part 212 acquires the plurality of frame images generated by the frame image generation part 211 and stored in the memory part 21. The probability distribution determination part 213 determines a probability distribution of brightness following the lognormal distribution for each pixel from the plurality of frame images acquired by the acquisition part 212. The artificial image generation part 214 generates artificial frame image of a specified number of frames (e.g., 1024 frames) based on the probability distribution of brightness for each pixel. Then, the artificial image generation part 214 generates artificial images corresponding to the images obtained by averaging the artificial frame images of the specified number of frames.

The pitch measurement part 202 measures the pitch of a pattern having periodic irregularities on the wafer W based on the result of scanning of the electron beam with respect to the wafer W. The result of scanning of the electron beam with respect to the wafer W is, for example, the image of the wafer W generated by the measurement image generation part 201, specifically, the artificial image generated by the artificial image generation part 214.

The feature amount measurement part 203 measures the feature amount (e.g., the line width) other than the pitch of the pattern based on the result of scanning of the electron beam with respect to the wafer W, the measurement result of the pitch measurement part 202 and a design value of the pitch of the pattern. The result of scanning of the electron beam with respect to the wafer W is, for example, the image of the wafer W generated by the measurement image generation part 201, specifically, the artificial image generated by the artificial image generation part 214.

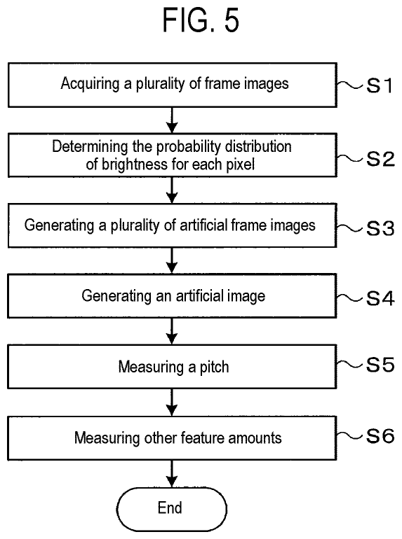

FIG. 5 is a flowchart illustrating a process performed in the controller 22. In the following process, it is assumed that the scanning electron microscope 10 has previously perform the scanning of the electron beam under the control of the controller 22 for the number of frames specified by the user, and the frame image generation part 211 has generated the frame images for the number of frames specified as above. Further, it is assumed that the generated frame images are stored in the memory part 21. In addition, it is assumed that a line-and-space pattern is formed on the wafer W.

In the process of the controller 22, the acquisition part 212 first acquires the frame images for the number of frames specified above from the memory part 21 (step S1). The number of frames specified above is, for example, 32, and may be larger or smaller than 32 as long as the number of frames is plural. The image size and the imaging region are common among the acquired frame images. Further, the image size of the acquired frames is, for example, 1,000 pixels×1,000 pixels, and the size of the imaging region is 1,000 nm×1,000 nm.

Next, the probability distribution determination part 213 determines the probability distribution of brightness for each of the pixels following the lognormal distribution (step S2). Specifically, the lognormal distribution is represented by the following equation (1). For each of the pixels, the probability distribution determination part 213 calculates two specific parameters μ and σ that determine the lognormal distribution followed by the probability distribution of brightness of the corresponding pixel.

$$f ( x ) = \frac{1}{\sqrt{2 π} σ x} exp ( - \frac{{( ln x - μ )}^{2}}{2 {σ}^{2}} ) , 0 < x < ∞ \qquad ( 1 )$$

Subsequently, the artificial image generation part 214 sequentially generates artificial frame images as artificial frame images for the number of frames specified by the user, based on the probability distribution of brightness for each of the pixels (step S3). In order to reduce image noise, the number of frames of the artificial frame images may be plural, but may preferably be larger than the number of frames in the original frame images. Furthermore, the size of the artificial frame images is equal to the size of the original frame images. Specifically, the artificial frame images are images in which the brightness of each of the pixels is set as a random number value generated according to the aforementioned probability distribution. That is, in step S3, for example, for each of the pixels, the artificial image generation part 214 generates a random number just as much as the number of specified frames from the two specific parameters μ and σ that determine the lognormal distribution followed by the probability distribution calculated for each of the pixels in step S2.

Next, the artificial image generation part 214 averages the generated artificial frame images to generate an artificial image (step S4). The size of the artificial image is the same as the size of the original frame images or the artificial frame images. Specifically, in step S4, for each of the pixels of the artificial frame images, the random number values of the number corresponding to the number of specified frames generated in step S3 are averaged, and the averaged value is used as the brightness of the pixel of the artificial image corresponding to each of the pixels of the artificial frame images.

Then, the pitch measurement part 202 measures the pitch of the pattern on the wafer W based on the artificial image generated by the artificial image generation part 214 (step S5). Specifically, as in the conventional case, the pitch measurement part 202 detects an edge of the line-and-space pattern formed on the wafer W from the artificial image generated by the artificial image generation part 214. Then, the pitch measurement part 202 measures the pitches of the spaces in the pattern based on the detection result of the edge and the information on the length per pixel in the artificial image stored in advance. More specifically, the pitch measurement part 202 calculates an in-plane average of the pitches of the spaces in the artificial image. The pitches of the spaces are, for example, the distances between the centers of spaces adjacent to each other. The artificial image may be displayed on the display part 23 simultaneously with, or before and after, the measurement performed by the pitch measurement part 202 and the measurement performed by the feature amount measurement part 203.

Subsequently, the feature amount measurement part 203 measures feature amounts other than the pitch of the pattern formed on the wafer W, based on the artificial image generated by the artificial image generation part 214, the pitch measured by the pitch measurement part 202, and the design value of the pitch (step S6). Specifically, for example, first, as in the conventional case, the feature amount measurement part 203 detects an edge of the line-and-space pattern formed on the wafer W from the artificial image generated by the artificial image generation part 214. Further, the feature amount measurement part 203 measures a line width L₀ of the pattern as another feature amount of the pattern based on the detection result of the edge and the information of the length per pixel in the artificial image stored in advance. Then, the feature amount measurement part 203 corrects the line width L₀ based on a ratio of the in-plane average Pₐᵥₑ of the pitches of the spaces in the artificial image and the design value P_{d} of the pitch. For example, the feature amount measurement part 203 corrects the line width L₀ based on the following equation (2) and acquires a corrected line width Lₘ.

Lₘ=L₀/(Pₐᵥₑ/P_{d}) (2)

Specifically, the design value P_{d} of the pitch of the space in the line-and-space of the pattern formed on the wafer W is determined from the pitch of the pattern formed on the mask used for the exposure process of the wafer W.

Other feature amounts of the pattern measured by the feature amount measurement part 203 are not limited to the aforementioned line width, and may be, for example, at least one of a line width roughness (LWR), a line edge roughness (LER), the width of the space between the lines and the center of gravity of the pattern.

Each of the above-described steps is performed for each region when the wafer W is divided into a plurality of regions.

As described above, the method of measuring the feature amount of the pattern formed on the wafer W and provided with periodic irregularities according to the present embodiment includes: (A) a step of measuring a pitch of the pattern based on the result of scanning of the electron beam with respect to the wafer W; and (B) a step of measuring feature amounts other than the pitch of the pattern based on the result of the scanning, and correcting the measurement result based on the ratio of the pitch measurement result obtained in the above step (A) to the pitch design value. As described above, the mask position at the time of exposure is strictly controlled. Therefore, the pitch of the pattern formed on the wafer W is not changed significantly from the design value. Nevertheless, the deviation of the pitch measurement result from the design value is considered to be due to the imaging conditions of the scanning electron microscope, the warp of the wafer, the distortion during exposure, and the like. In particular, it is considered that in the local region such as the imaging range of the scanning electron microscope, the imaging conditions of the scanning electron microscope are the main cause of the deviation of the pitch measurement result from the design value. Therefore, in the method of measuring the feature amount according to the present embodiment, the aforementioned other feature amounts of the pattern are corrected by using not only the result of scanning of the electron beam on the wafer W (the artificial image in the present embodiment) but also the information on the pitch measurement result in the above step (A) and the information on the design value of the pitch. Specifically, in the measurement method, the other feature amounts of the pattern are measured based on the result of scanning of the electron beam on the wafer W, and the measurement result is corrected based on the ratio of the pitch measurement result obtained in the above step (A) to the design value of the pitch. As a result, the influence of the imaging conditions of the scanning electron microscope and the like can be removed from the measurement results of other feature amounts of the pattern. Accordingly, in the feature amount measurement method according to the present embodiment, it is possible to accurately measure the other feature amounts of the pattern.

For example, when the exposure region is about 32 mm×26 mm, the exposure conditions such as a mask position and the like at the time of exposure are managed so that the deviation in the entire exposure region becomes about 5 nm. Nevertheless, according to the investigation conducted by the present inventors, when the imaging region is about 1,000 nm 1,000 nm, there was a case where the pitch measured based on the scanning result of the electron beam under the condition that the design value of the pitch is 45 nm is larger than the design value by 0.63 to 1.41 nm in the entire region of the wafer. A difference Δ between the maximum value and the minimum value of the measured pitch was 0.76 nm, and 3σ of the measured pitch was 0.23 nm. In this case, when the measurement result of the line width of the pattern is not corrected unlike the method of measuring a feature amount according to the present embodiment, the average value of the line widths in the wafer plane was 21.60 nm, and 3σ was 0.94. On the other hand, when the measurement result of the line width of the pattern is corrected as in the method of measuring a feature amount according to the present embodiment, the average value was 21.18 nm, and 3σ was 0.92 nm. That is, a difference of 0.42 nm in the line width measurement result was generated between the case where correction is performed as in the method of measuring a feature amount according to the present embodiment and the case where the feature amount is not corrected as in the conventional case. The line width measurement result is used for production process management. Therefore, the difference of 0.42 nm is an unacceptable difference in the production process management. In other words, by using the line width information measured by the method according to the present embodiment, it is possible to appropriately adjust the processing conditions for pattern formation on the wafer W.

In addition, unlike the present embodiment, for example, a method of measuring a feature amount of a pattern as follows may be considered. That is, calibration by simple addition and subtraction is performed in advance on the scanning electron microscope so that the average value of the pitches measured based on the scanning result of the electron beam becomes equal to the design value of the pitch. After the calibration, a feature amount of a pattern is measured based on the scanning result of the electron beam. However, in the calibration performed by this method, even if the average value of the pitches measured based on the scanning result of the electron beam is improved, the variation of the pitches is not improved. Even if the feature amount of the pattern is measured based on the scanning result of the electron beam after such calibration, it is not possible to obtain an accurate measurement result.

One of the causes that the measured pitch of the pattern deviates from the design value is considered to be the distortion of the wafer caused by the imaging conditions of the scanning electron microscope 10. According to the present embodiment, it is possible to exclude the influence of the distortion.

Further, in the present embodiment, the average value of the pitches of the pattern in the image is used to correct the measurement result of the other feature amounts of the pattern. Therefore, even if a distortion derived from the scanning electron microscope 10 exists in the image used for pitch measurement or the like, the influence of the distortion can be excluded from the pitch measurement result used for the correction.

Further, in the present embodiment, the pitch of the concave portion of the pattern is used as the pitch of the pattern having irregularities on the wafer W. More specifically, the distance between the centers of spaces adjacent to each other is used. The reason is as follows. When forming a pattern, SADP (Self-Aligned Double Patterning) or SAQP (Self-Aligned Quadruple Patterning) may be used. In this case, the distance between the centers of convex portions such as lines adjacent to each other varies due to pitch walking, but the distance between the centers of the concave portions, i.e., the spaces adjacent to each other is relatively stable. Therefore, in the present embodiment, the distance between the centers of the spaces adjacent to each other is used.

The artificial image generated by the control device 20 will be described below. In the following description, it is assumed that a line-and-space pattern is formed in the imaging region of the wafer W.

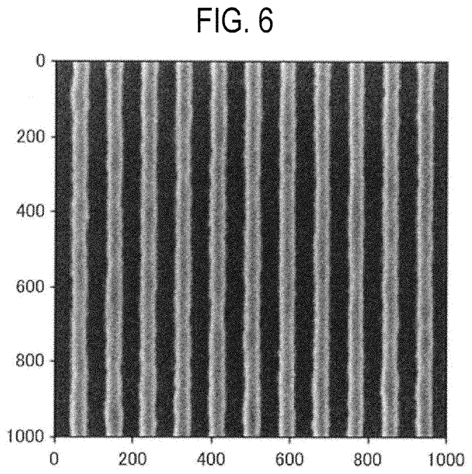

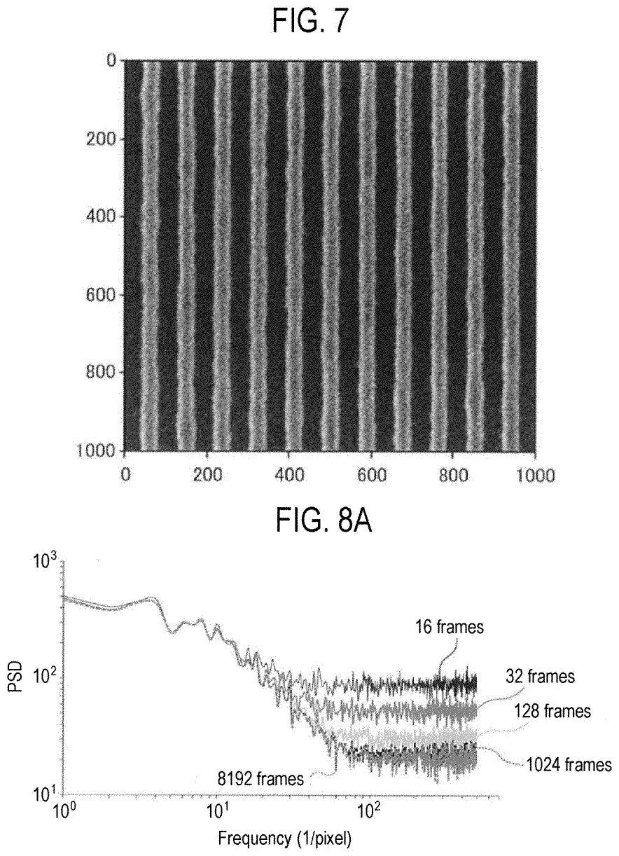

FIG. 6 shows an averaged image of frame images of 256 frames, and FIG. 7 shows an artificial image obtained by averaging the 256-frame artificial frame images generated based on the frame image of 256 frames used for the image generation of FIG. 6. As shown in FIGS. 6 and 7, the artificial image has substantially the same content as the image obtained by averaging the original frame images. That is, in the present embodiment, it is possible to generate an artificial image having the same content as the original image.

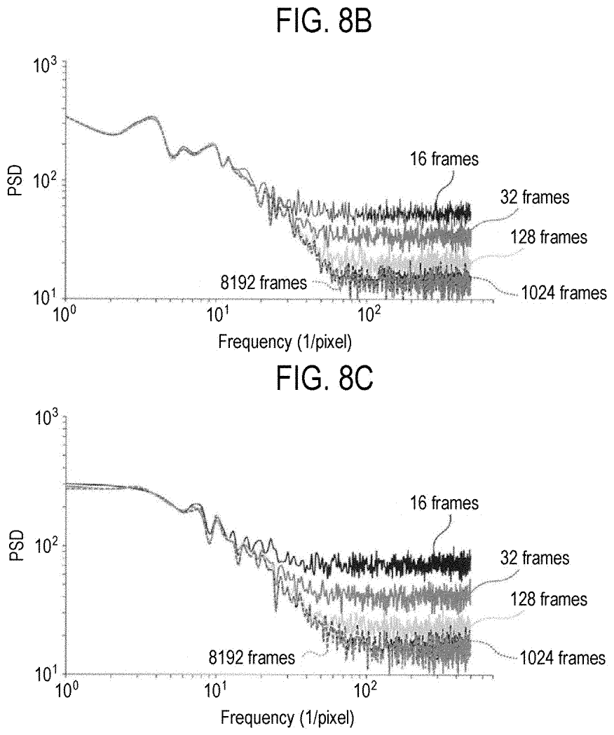

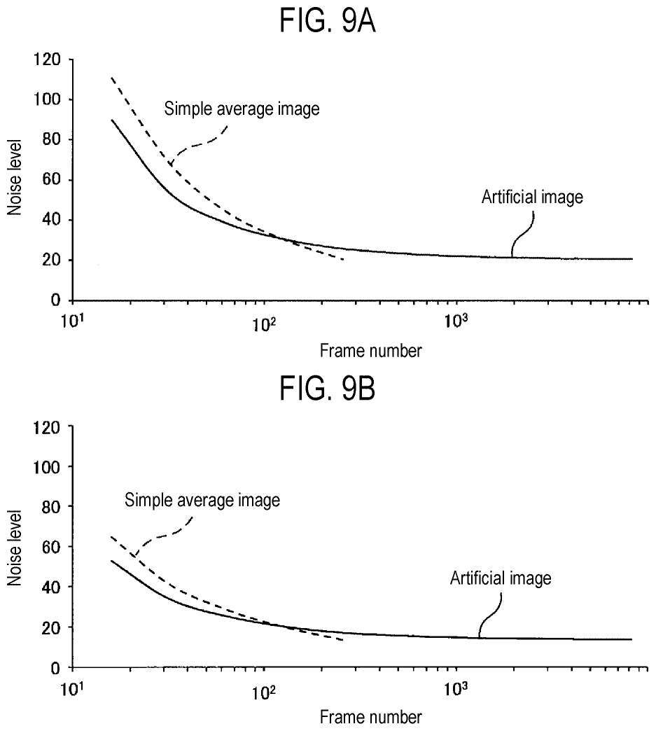

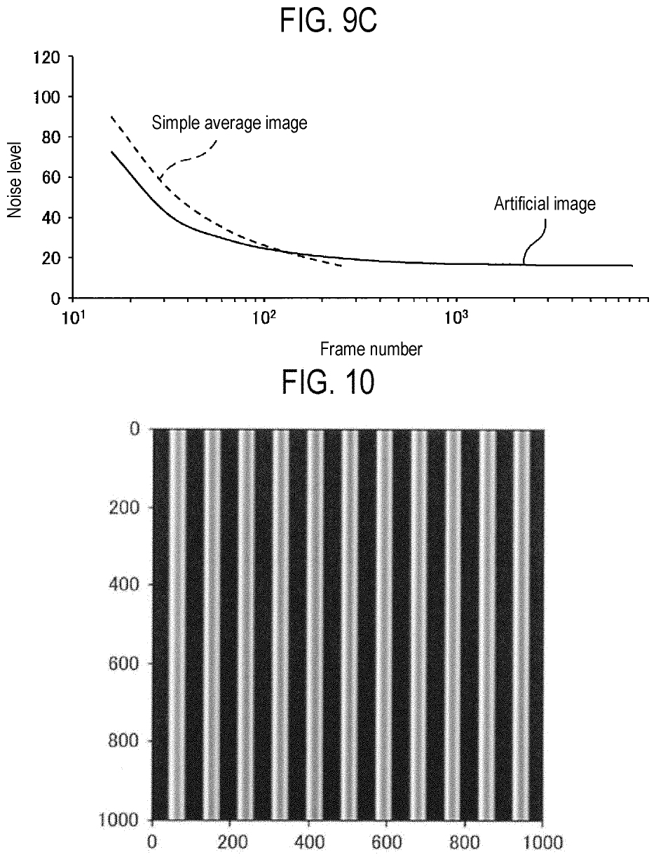

FIGS. 8A to 8C and FIGS. 9A to 9C are diagrams showing the frequency analysis results in the artificial image generated from the 256 frame images. FIGS. 8A to 8C show a relationship between the frequency and the amount of vibration energy (PSD: Power Spectrum Density). FIGS. 9A to 9C show a relationship between the number of frames of the artificial frame image used for the artificial image, or the number of frames of the frame image used for a simple averaged image described later, and a noise level of the high frequency component. In this regard, the high frequency component means a part where the frequency in the frequency analysis is 100 (1/pixel) or more, and the noise level is the average value of PSD of the high frequency component. Further, FIGS. 8A and 9A show the frequency analysis results for the LWR of the line of the pattern. FIGS. 8B and 9B show the frequency analysis results for the LER on the left side of the line (hereinafter referred to as LLER). FIGS. 8C and 9C show the frequency analysis results for the LWR on the right side of the line (hereinafter referred to as RLER). Furthermore, in FIGS. 9A to 9C, there are also shown the frequency analysis results for an image obtained by averaging the first N (N is a natural number of 2 or more) images among the 256 original frame images (hereinafter, the image obtained by averaging the frame images will be referred to as a simple averaged image). In this regard, the image obtained by averaging the N images refers to an image obtained by simply averaging, i.e., arithmetically averaging the brightness for each pixel. Furthermore, in the frequency analysis of the image conducted herein, a simple smoothing filter or a Gaussian filter generally used for the frequency analysis of the image is not used at all.

In the frequency analysis of LWR in the artificial image, as shown in FIG. 8A, the PSD of the high frequency component decreases as the number of frames of the artificial frame images used for the artificial image increases. Further, as shown in FIG. 9A, the noise level decreases as the number of frames of the artificial frame images increases. However, the noise level does not become zero but remains constant at a certain positive value. As shown in FIGS. 8B and 8C and FIGS. 9B and 9C, the same applies to the frequency analysis of LLER and RLER. In other words, in the ultra-high frame artificial images, image noise is removed, but a certain amount of noise remains. This noise is considered to be process-derived stochastic noise (hereinafter sometimes abbreviated as process noise).

It is impossible to actually form a pattern in which a process noise is zero. Thus, a plurality of frame images of the wafer W having zero process noise is virtually created, and an artificial frame image and an artificial image are generated from the frame images. The n^{th} frame image with zero process noise, which is virtually created here, is an image in which the brightness of pixels having a common X coordinate is equal to an average value of brightness of pixels having the same X coordinate in the n^{th} actual frame image.

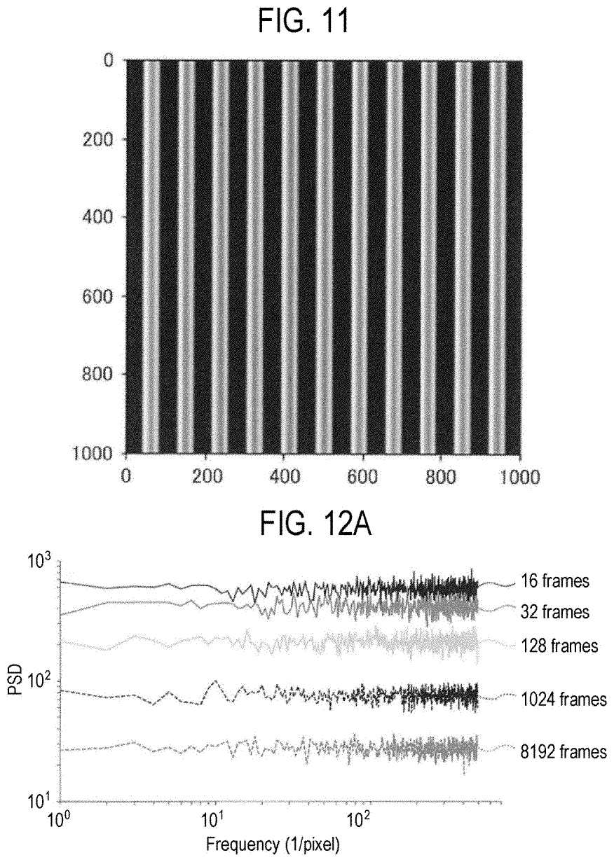

FIG. 10 is an averaged image of 256 virtual frame images having zero process noise. FIG. 11 shows an artificial image. This artificial image is obtained by generating artificial frame images of 256 frames based on the above virtual frame images of 256 frames used for generation of the image of FIG. 10, and averaging these artificial frame images. As shown in FIGS. 10 and 11, even when the virtual frame images having zero process noise are used, the artificial image has substantially the same content as the image obtained by averaging the original virtual frame images.

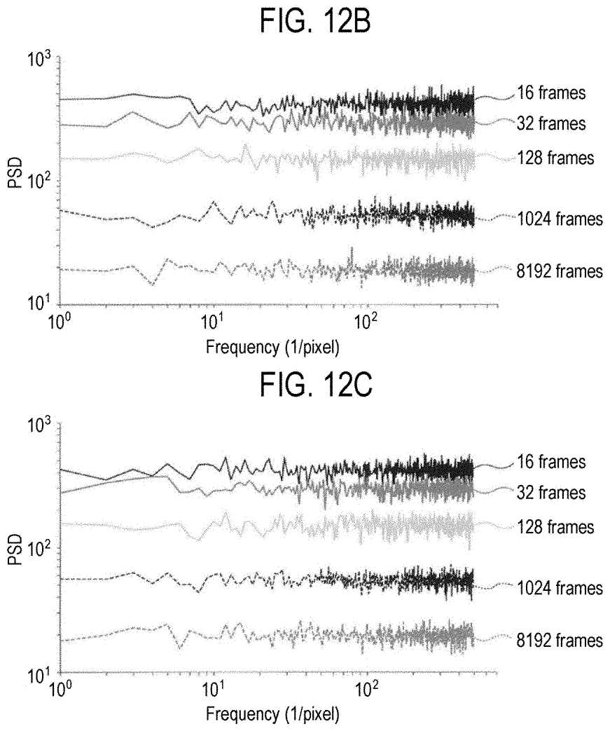

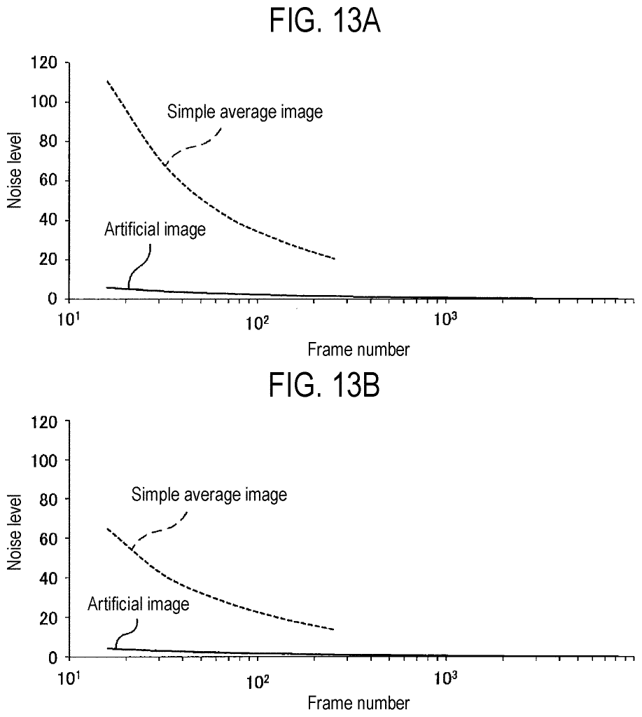

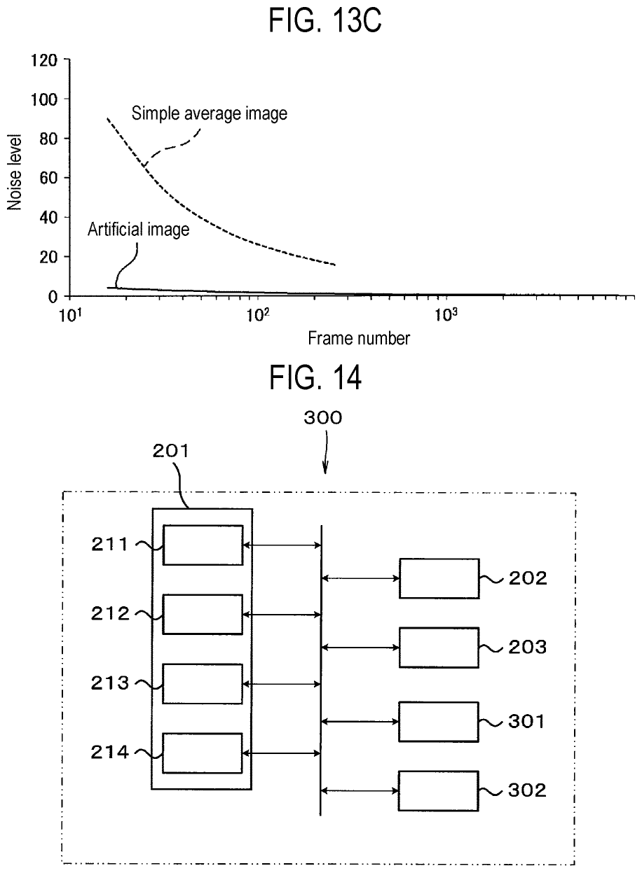

FIGS. 12A to 12C and FIGS. 13A to 13C are diagrams showing the frequency analysis results in the artificial images generated from 256 virtual frame images having zero process noise. FIGS. 12A to 12C show a relationship between the frequency and the PSD. FIGS. 13A to 13C show a relationship between the number of frames of the artificial frame images used for the artificial image and the noise level of the high frequency component. Further, FIGS. 12A and 13A show the frequency analysis results for LWR. FIGS. 12B and 13B show the frequency analysis results for LLER, and FIGS. 12C and 13C show the frequency analysis results for RLER. It should be noted that FIGS. 13A to 13C also show the frequency analysis results for the aforementioned simple averaged image.

When the virtual frame image having zero process noise is used, during the frequency analysis of LWR in the artificial image, as shown in FIG. 12A, PSD decreases as the number of frames of the artificial frame images used for the artificial image increases. Further, as shown in FIG. 13A, the noise level decreases as the number of frames of the artificial frame images increases. The noise level becomes almost zero when the number of frames is a certain number or more (e.g., 1,000 or more). As shown in FIGS. 12B and 12C and FIGS. 13B and 13C, the same applies to the frequency analysis of LLER and RLER. That is, when the process noise is zero, the image noise is removed from the ultra-high frame artificial images, and the noise of all the images becomes zero.

(i) As described above, when there is process noise, the noise level decreases as the number of frames of the artificial frame images increases, but the noise in the artificial image does not become zero even if the number of frames of the virtual frame images is very large. (ii) Further, when the process noise is virtually zero, if the number of frames of the virtual frame image is large, the noise in the artificial image becomes zero. From the above (i) and (ii), it can be said that the artificial image is an image in which only the image noise is removed and the process noise is left.

Further, the artificial image can be obtained even if the number of frames of the actual frame images obtained by the scanning of the electron beam is small. The smaller the number of frames of the actual frame images used for the generation of the artificial image, the less the pattern on the wafer is damaged by the electron beam. Therefore, the artificial image is an image having a pattern that is not damaged by the electron beam, i.e., an image that reflects more accurate process noise.

### Second Embodiment

FIG. 14 is a block diagram showing an outline of a configuration related to an image processing process and a feature amount calculation process of a controller 300 included in a control device as a feature amount measurement device according to a second embodiment. The controller 300 according to the present embodiment includes a filter part 301 and a calculation part 302 in addition to the measurement image generation part 201, the pitch measurement part 202 and the feature amount measurement part 203.

The filter part 301 filters the image obtained from the result of scanning of the electron beam on the wafer W. The image obtained from the result of scanning of the electron beam on the wafer W is, for example, an image of the wafer W generated by the measurement image generation part 201, more specifically, an artificial image generated by the artificial image generation part 214. The filtering may be either real space filtering or frequency space filtering. In the case of the real space filtering, it may be possible to use smoothing filters such as a Sobel filter, a Roberts filter, a Canny filter, a Gaussian filter, a simple smoothing filter, a box filter, a median filter, and the like. In the case of the frequency space filtering, it may be possible to use, for example, a low-pass filter.

The calculation part 302 calculates a blur value (B value) indicating the degree of blurring of the original image based on the original image before filtering and the image after filtering. The blur value also indicates the amount of change in the brightness in the image due to filtering, and is calculated for each pixel based on a difference between the brightness of the original image and the brightness of the filtered image. Specifically, the calculation part 302 calculates the blur value based on, for example, the image of the original wafer W before filtering, which is generated by the measurement image generation part 201, and the image of the wafer W after filtering. More specifically, the calculation part 302 calculates the blur value based on the original artificial image before filtering, which is generated by the artificial image generation part 214, and the artificial image after filtering.

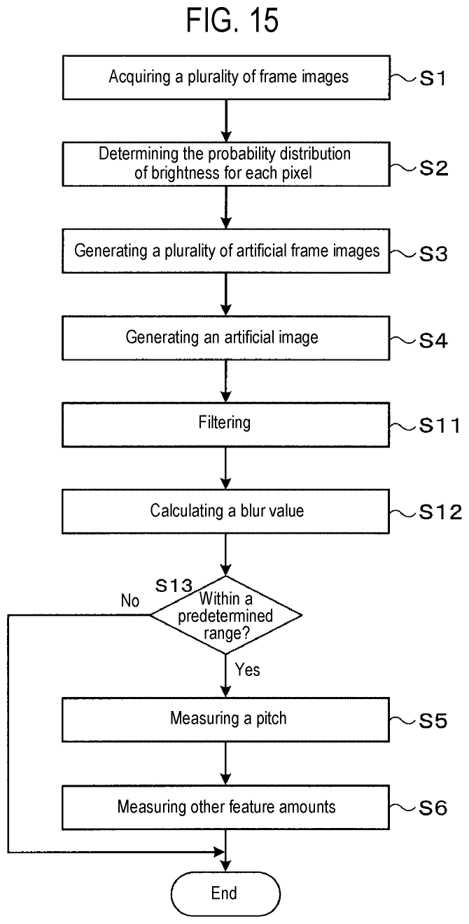

FIG. 15 is a flowchart illustrating a process performed by the controller 300. In the process performed by the controller 300, after step S4, i.e., after the artificial image is generated, the filter part 301 filters the artificial image generated by the artificial image generation part 214, by using the Sobel filter (step S11).

Next, the calculation unit 302 calculates a blur value B indicating the degree of blurring of the original artificial image, based on the original artificial image before filtering, which is generated by the Sobel filter, and the artificial image after the filtering (step S12). The blur value B is calculated based on, for example, any of the following equations (3) to (5). In the equations (3) to (5), p denotes the number of pixels of the artificial image, c_{x,y} denotes the brightness value of the pixel at the coordinates (x,y) in the original artificial image, s_{x,y} denotes the brightness value of the pixel at the coordinates (x,y) in the artificial image after filtering, and b denotes the number of bits of the artificial image (e.g., 8 for 256 gradations, and 16 for 65536 gradations).

$$\begin{matrix}B = {[ \frac{1}{p} \sum {( {c}_{x , y} - {s}_{x , y} )}^{2} ]}^{0.5} & ( 3 ) \\ B = {[ \frac{1}{p} \sum ( {c}_{x , y}^{2} - {s}_{x , y}^{2} ) ]}^{0.5} & ( 4 ) \\ B = {[ \frac{1}{bp} \sum {( {c}_{x , y} - {s}_{x , y} )}^{2} ]}^{0.5} & ( 5 )\end{matrix}$$

Then, the controller 300 determines whether or not the blur value B of the original artificial image before filtering falls within a predetermined range (step S13). Specifically, the controller 300 determines whether or not the blur value B is smaller than a threshold value. The threshold value is previously determined according to the type of pattern formed on the wafer W and the size of the pattern (e.g., the line width), and is stored in the memory part 21. Further, the threshold value is set, for example, when creating an imaging recipe in the scanning electron microscope 10.

When the blur value B falls within the predetermined range, i.e., when the blur value B is larger than the threshold value (when YES in step S13), the measurement of the pitch by the pitch measurement part 202 and the measurement of other feature amounts by the feature amount measurement part 203 are performed based on the original artificial image before filtering. On the other hand, when the blur value B does not fall within the predetermined range, i.e., when the blur value B is smaller than the threshold value (when NO in step S13), the measurement of the pitch by the pitch measurement part 202 and the measurement of other feature amounts by the feature amount measurement part 203 are not performed. In this way, the original artificial image whose blur value B does not within the predetermined range is excluded from the artificial images used in the other feature amount measurement step.

In the case where the pattern formed on the wafer W is a pattern in which pillars are formed on a line-and-space pattern, when a Sobel filter is used, a filter that detects edges in a direction corresponding to the shape of the pattern is used. Details thereof are as follows.

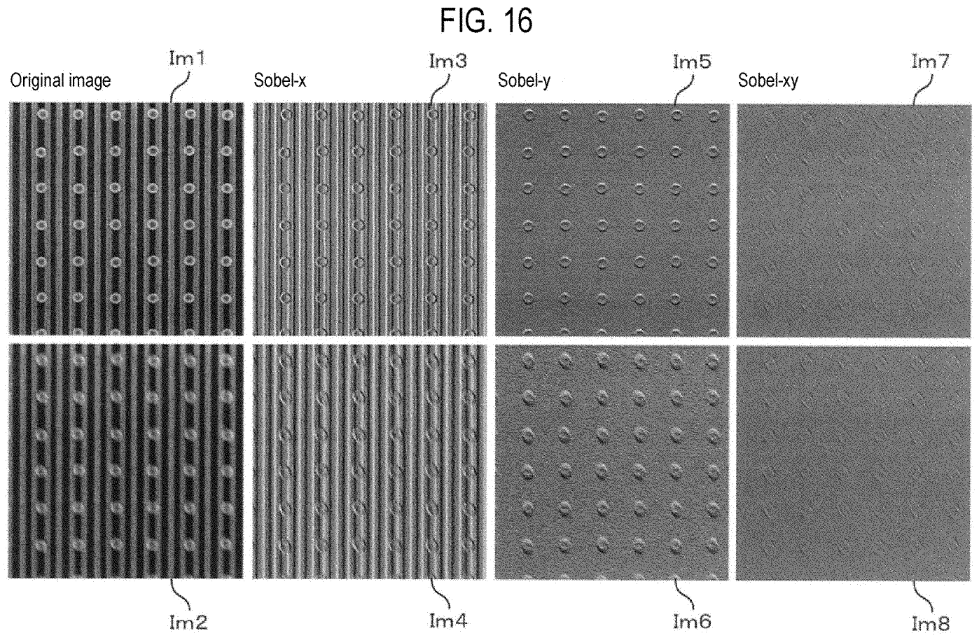

FIG. 16 is a diagram showing an example of images before and after filtering. Image Im1 and image Im2 of FIG. 16 are artificial images before filtering of the wafer W in which pillars are formed on the line-and-space pattern. The image Im2 is more blurred than the image Im1.

Image Im3 is an image obtained by filtering the image Im1 through the use of the Sobel filter Sobel-x that smoothens an image in the direction in which a line extends (the vertical direction in FIG. 16). Image Im4 is an image obtained by filtering the image Im2 through the use of the Sobel filter Sobel-x. The brightness is not changed much between the image Im1 and the image Im2. The brightness of the image Im3 and the image Im4 is higher than that of the image Im1 and the image Im2. In particular, the image Im3 has higher brightness as a whole. That is, the amount of change in brightness between the blurred image Im2 and the filtered image Im4 is smaller than the amount of change in brightness between the non-blurred image Im1 and the filtered image Im3. Further, when the brightness value is given in 16 bits, the blur value B given by the above equation (3), which can be calculated based on the images Im1 to Im4, is 955 for the image Im1 and 739 for the image Im2, the difference of which is 216.

Image Im5 is an image obtained by filtering the image Im1 through the use of a Sobel filter Sobel-y that smoothens an image in the direction orthogonal to the direction in which a line extends (the vertical direction in FIG. 16). Image Im6 is an image obtained by filtering the image Im2 through the use of the Sobel filter Sobel-y. The brightness of the image Im5 and the image Im6 is higher than that of the image Im1 and the image Im2. In particular, the image Im5 has higher brightness as a whole. That is, the amount of change in brightness between the blurred image Im2 and the filtered image Im6 is smaller than the amount of change in brightness between the non-blurred image Im1 and the filtered image Im5. Further, when the brightness value is given in 16 bits, the blur value B given by the above equation (3), which can be calculated based on the images Im1, Im2, Im5 and Im6, is 491 for the image Im1 and 387 for the image Im2, the difference of which is 104.

Image Im7 is an image obtained by filtering the image Im1 through the use of a Sobel filter Sobel-xy that smoothens an image in the direction in which a line extends (the vertical direction in FIG. 16) and in the direction orthogonal to the direction in which a line extends (the horizontal direction in FIG. 16). Image Im8 is an image obtained by filtering the image Im2 through the use of the Sobel filter Sobel-xy. The brightness of the image Im7 and the image Im8 is higher than that of the image Im1 and the image Im2. The brightness remains almost the same between the image Im7 and the image Im8. That is, the amount of change in brightness between the blurred image Im2 and the filtered image Im8 is the same as the amount of change in brightness between the non-blurred image Im1 and the filtered image Im7. Further, when the brightness value is given in 16 bits, the blur value B given by the above formula (3), which can be calculated based on the images Im1, Im2, Im7 and Im8, is 138 for the image Im1 and 136 for the image Im2, the difference of which is 2. When the difference in the blur value B is small between the case where the original image before filtering is blurred and the case where the original image before filtering is not blurred, it is difficult to determine, using the blur value, whether or not the original image before filtering is blurred.

Therefore, in the case where the pattern formed on the wafer W is a pattern in which pillars are formed on the line-and-space pattern, when the Sobel filter is used, a filter that smoothens an image in the direction corresponding to the shape of the pattern, specifically, a Sobel filter Sobel-x or a Sobel filter Sobel-y may be used. The Sobel filter Sobel-x is more preferable. In the case where the pattern formed on the wafer W is a line-and-space pattern, when the Sobel filter is used, a filter that smoothens an image in the direction in which a line extends may be used.

Hereinafter, the effects of the method of measuring a feature amount of a pattern according to the present embodiment will be described.

In the case where an image is blurred, for example, when the line width of the pattern on the wafer W is measured from the image, a measurement result larger than the actual line width may be obtained. On the other hand, when the focus is shifted during the exposure process and when the exposure amount is not appropriate, the line width may actually be larger or smaller than a desired value. Therefore, even if the line width of the pattern on the wafer W is equal to the desired value and the image used for the measurement is blurred, or even if the line width of the pattern on the wafer W is larger than the desired value, the line width is calculated as a large line width in both cases when the line width is measured based on the image. Accordingly, if blurring in the image used for the measurement is not taken into consideration unlike the present embodiment, when the measurement result of the line width is larger than the desired value, it may be mistakenly determined that the focus is shifted or the fluctuation of the exposure amount occurs during the exposure process. That is, when the B value is not adopted, the measurement result of the line width based on the image scanned with the electron beam may not be accurately interpreted.

On the other hand, the method according to the present embodiment includes a step of filtering the image obtained from the result of scanning of the wafer W with the electron beam, and a step of calculating the blur value B indicating the degree of blurring of the original image based on the original image before filtering and the image after filtering. Accordingly, by excluding the original image before filtering whose blur value B does not fall within the predetermined range from the original images used in the step of measuring the feature amount other than the pitch, etc., it is possible to accurately interpret the measurement result of the line width based on the image scanned with the electron beam.

In the above description, when the blur value B of the original image before filtering does not fall within the predetermined range, the original image is excluded from the images used in the above-mentioned other feature amount measurement step. Alternatively, when the blur value B of the original image before filtering does not fall within the predetermined range, the other feature amounts may be measured from the original image, and the measurement result may be excluded from the pattern analysis result.

Furthermore, when the blur value B of the original image before filtering does not fall within the predetermined range, the controller 300 may perform a removal process of removing the blurring from the original image. In this case, the measurement of the other feature amounts is performed based on the original image when the blur value of the original image falls within the predetermined range, and is performed based on the original image after the removal process when the blur value of the original image does not fall within the predetermined range. Even when the blur value of the original image does not fall within the predetermined range, the pitch may be measured based on the original image, or may be measured based on the original image after the removal process.

Furthermore, when the blur value B of the original image before filtering does not fall within the predetermined range, under the control of the controller 300, the original image before filtering may be reacquired for the region on the wafer from which the original image is acquired. The electron beam irradiation region, i.e., the imaging region at the time of reacquiring the original image is set at a position different from that at the time of the previous acquisition of the original image. This is to reduce the damage to the wafer which may be caused by the electron beam.

Furthermore, when the blur value B of the original image before filtering falls within the predetermined range, the operator may perform maintenance on the scanning electron microscope 10. Moreover, the fact or warning that maintenance is required may be displayed on the display part 23, or may be notified by a voice output means (not shown) or the like.

Also in this embodiment, a raw image (a frame integrated image or each frame image constituting the frame integrated image) may be used as the scanning image. For example, in this case, if the blur value of the raw image falls within a predetermined range, i.e., if the raw image is not blurred, the raw image is used for measuring the feature amount of the pattern. If the blur value of the raw image does not fall within the predetermined range, i.e., if the raw image is blurred, a warning or the like is issued.

As described above, the threshold value for the blur value B is set, for example, when creating an imaging recipe in the scanning electron microscope 10. When creating the imaging recipe, for example, a measurement image is registered, and a blur value B and a likelihood AB thereof for the measurement image are registered. Then, at the time of measurement, when the blur value B of the newly created measurement image falls below a value obtained by subtracting the likelihood AB from the registered blur value B, the newly created measurement image may be determined to be blurred. Therefore, a warning or the like is issued.

In the above description, whether or not to measure the feature amount based on the measurement image, i.e., whether or not the measurement image is blurred, is determined based on the blur value B. However, whether or not the measurement image is blurred may be determined as follows. That is, a predetermined machine learning module may be allowed to learn a blurred image and a non-blurred image, and the machine learning module may be allowed to determine whether or not the measurement image is blurred. In this case, the machine learning module can calculate the similarity to the input image. For example, whether or not the measurement image is blurred is determined based on both the similarity to the non-blurred image and the similarity to the blurred image. More specifically, for example, when the similarity between the measurement image and the non-blurred image is X1(%) and the similarity between the measurement image and the blurred image is X2(%), it is determined whether or not the measurement image is blurred, based on a value Y given from the calculation equation, Y=X1/(X1+X2).

### Third Embodiment

In the above-described embodiment, the artificial image generation step is composed of two steps, i.e., step S3 and step S4. In the present embodiment, the number of frames of the artificial frame images used for the artificial image is infinite. In such a case, the artificial image generation step may be configured by one step, i.e., a step in which the artificial image generation part 214 generates, as an artificial image, an image in which the brightness of each pixel is used as an expected value of the probability distribution of brightness. The expected value can be expressed by the following formula (6) using specific parameters μ and σ of the lognormal distribution followed by the probability distribution of brightness of each pixel.

exp(μ+σ₂/2) (6)

In the following description, an artificial image in which the number of frames of the artificial frame images used is infinite will be referred to as infinite-frame artificial image.

According to the present embodiment, it is possible to generate an image in which only the image noise is removed and the process noise is left, at a reduced computational complexity.

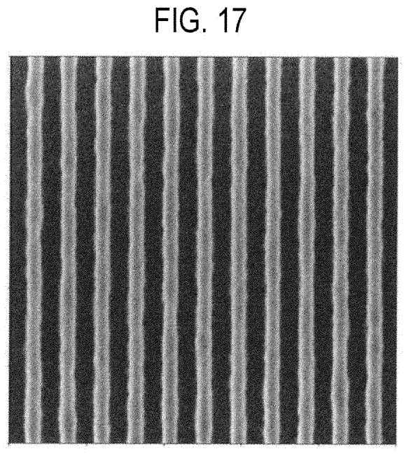

FIG. 17 shows an infinite-frame artificial image generated by the method according to the third embodiment. As shown in FIG. 17, according to the present embodiment, it is possible to obtain a clearer artificial image.

### Fourth Embodiment

In the first embodiment or the like, the artificial image generation part 214 generates one artificial image through the use of a random number based on the probability distribution of brightness for each pixel, and the pitch measurement part 202 and the feature amount measurement part 203 perform measurement based on the one artificial image.

On the other hand, in the present embodiment, the artificial image generation part 214 generates a plurality of artificial images through the use of a random number based on the probability distribution of brightness for each pixel. Then, the pitch measurement part 202 and the feature amount measurement part 203 measure the pitch of the pattern or other feature amounts based on the plurality of artificial images.

Specifically, in the present embodiment, the artificial image generation part 214 generates Q artificial images by repeating, Q(Q≥2) times: (X) generating P(P≥2) artificial frame images by generating a random number from two specific parameters μ and σ that determine the lognormal distribution followed by the probability distribution of brightness for each pixel; and (Y) generating an artificial image by averaging the generated P artificial frame images. For each of the plurality of artificial images, i.e., the Q artificial images, the pitch measurement part 202 calculates edge coordinates of the pattern on the wafer, and calculates and acquires an average value of the edge coordinates as a statistical value of the edge coordinates from the calculated Q edge coordinates. The pitch measurement part 202 measures the pitch of the pattern based on the acquired average value of the edge coordinates of the pattern. Then, the feature amount measurement part 203 measures the other feature amounts of the pattern based on the acquired average value of the edge coordinates of the pattern, the value of the pitch measured by the pitch measurement part 202, and the design value of the pitch. More specifically, the feature amount measurement part 203 measures the other feature amounts of the pattern from the average value of the edge coordinates, and corrects the measurement result based on a ratio of the measured value of the pitch pursuant to the average value of the edge coordinates obtained by the pitch measurement part 202 to the design value of the pitch.

When the artificial image generation part 214 generates a plurality of artificial images through the use of a random number based on the probability distribution of brightness for each pixel as in the present embodiment, the filtering and the calculation of a blur value B may be performed on the artificial image as in the above-described second embodiment each time when the artificial image is generated. Then, for example, when an artificial image before filtering in which the blur value B does not fall within a predetermined range is obtained, the subsequent generation of the artificial image may be stopped. The reason is as follows. It is expected that the blur value B of the subsequently-generated artificial image before filtering will not fall within the predetermined range. The load on the controller 22 can be reduced by stopping the generation of such an artificial image.

### Fifth Embodiment

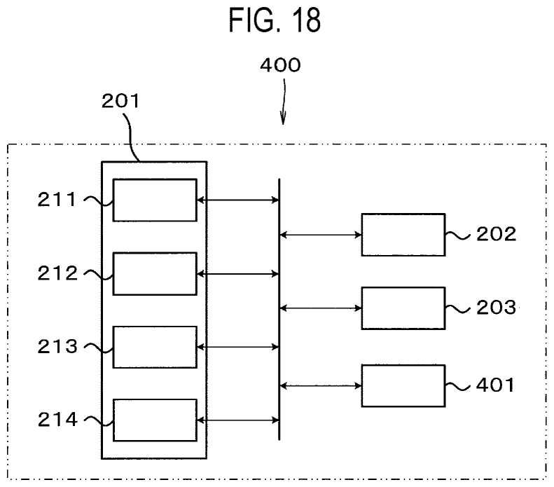

FIG. 18 is a block diagram showing an outline of a configuration related to an image processing process and a feature amount calculation process of a controller 400 included in a control device as a feature amount measurement device according to a fifth embodiment.

The controller 400 according to the present embodiment includes an analysis part 401 in addition to the measurement image generation part 201, the pitch measurement part 202 and the feature amount measurement part 203. The analysis part 401 analyzes the pattern based on the result of scanning of the electron beam on the wafer W, the measurement result of the pitch of the pattern obtained by the pitch measurement part 202, and the design value of the pitch. The result of scanning of the electron beam on the wafer W is, for example, an image of the wafer W generated by the measurement image generation part 201, specifically, an artificial image generated by the artificial image generation part 214. Specifically, for example, the analysis part 401 first detects an edge of the pattern formed on the wafer W from the artificial image generated by the artificial image generation part 214, as in the conventional case. Further, the analysis part 401 analyzes the pattern on the wafer W based on information on the detected edge of the detected pattern and information on the length per pixel in the artificial image stored in advance. The analysis performed by the analysis part 401 is, for example, at least one of the frequency analysis of line width roughness (LWR) of the pattern, the frequency analysis of edge roughness of the line and the frequency analysis of roughness of the center position (Line Placement Roughness) of the line.

In the above example, since the histogram in FIG. 4 follows the lognormal distribution, the probability distribution determination part 213 determines the probability distribution of brightness that follows the lognormal distribution for each pixel.

According to further studies conducted by the present inventors, the histogram in FIG. 2 follows the sum of a plurality of lognormal distributions, the Weibull distribution, or the gamma-Poisson distribution. The histogram in FIG. 2 also follows a combination of single lognormal distribution or a plurality of lognormal distributions and a Weibull distribution, a combination of a single lognormal distribution or a plurality of lognormal distributions and a gamma-Poisson distribution, and a combination of a Weibull distribution and a gamma-Poisson distribution. The histogram in FIG. 2 also follows a combination of a single lognormal distribution or a plurality of lognormal distributions, a Weibull distribution and a gamma-Poisson distribution. Therefore, it is only necessary that the probability distribution of brightness determined by the probability distribution determination part 213 for each pixel follows at least one of a lognormal distribution or a sum of lognormal distributions, a Weibull distribution and a gamma-Poisson distribution, or a combination thereof.

Further, in the above description, the frame image generated by the frame image generation part 211 is an image obtained by scanning the electron beam on the wafer W once. However, the frame image may be images obtained by scanning the electron beam on the same region of the wafer W a plurality of times.

Further, in the above description, the imaging target is assumed to be a wafer. However, the imaging target is not limited thereto, and may be, for example, other various kinds of substrates.

In the above description, the control device for the scanning electron microscope is used as the feature amount measurement device in each of the embodiments. In some embodiments, a host computer that performs analysis or the like based on an image of a processing result in a semiconductor manufacturing apparatus such as a coating-developing processing system or the like may be used as the feature amount measurement device according to each of the embodiments.

Further, in the above description, the charged particle beam is an electron beam. However, the charged particle beam is not limited thereto, and may be, for example, an ion beam.

In the above description, each of the embodiments has been described mainly by taking a process on an image of a line-and-space pattern as an example. However, each of the embodiments may also be applied to images of other patterns, such as an image of a contact hole pattern, an image of a pillar pattern, and the like.

According to the present disclosure in some embodiments, it is possible to accurately measure a feature amount of a pattern based on the result of scanning a substrate, on which the pattern is formed, with a charged particle beam.

It should be noted that the embodiments disclosed herein are exemplary in all respects and are not restrictive. The above-described embodiments may be omitted, replaced or modified in various forms without departing from the scope and spirit of the appended claims.

What is claimed is:

1. A method of measuring a feature amount of a pattern formed on a substrate and provided with periodic irregularities, comprising:
(A) measuring a pitch of the pattern based on a result of a scanning of a charged particle beam on the substrate; and
(B) measuring other feature amounts other than the pitch of the pattern based on the result of the scanning, and correcting the measurement result of the other feature amounts based on a ratio of the measurement result of the pitch obtained in (A) to a design value of the pitch.

2. The method of claim 1, wherein the pitch is a pitch of a recess of the pattern.

3. The method of claim 2, further comprising:
filtering an image obtained from the result of the scanning; and
calculating a blur value indicating a degree of blurring of an original image based on the original image before the filtering and a filtered image after the filtering.

4. The method of claim 1, further comprising:
filtering an image obtained from the result of the scanning; and
calculating a blur value indicating a degree of blurring of an original image based on the original image before the filtering and a filtered image after the filtering.

5. The method of claim 4, wherein the blur value is calculated based on a difference between brightness of the original image and brightness of the filtered image for each pixel.

6. The method of claim 5, wherein the filtering is performed using a Sobel filter, a Roberts filter, a Gaussian filter, a simple smoothing filter, a box filter, a median filter or a low-pass filter.

7. The method of claim 4, wherein the measurements in (A) and (B) are performed based on the original image, and the original image in which the blur value falls outside a predetermined range is excluded from the original image used in (B).

8. The method of claim 4, further comprising: performing a removal process of removing blurring from the original image in which the blur value falls outside a predetermined range,
wherein the measurement in (B) is performed based on the original image in which the blur value falls within the predetermined range, or the original image in which the blur value after the removal process falls outside the predetermined range.

9. The method of claim 4, wherein the measurements in (A) and (B) are performed based on the original image, and
the method further comprises:
reacquiring the original image for a region on the substrate from which the original image in which the blur value falls outside a predetermined range has been acquired.

10. The method of claim 1, further comprising:
(a) acquiring a plurality of frame images obtained by scanning a charged particle beam on the substrate;
(b) determining a probability distribution of brightness for each pixel from the plurality of frame images; and
(c) generating an image of the substrate corresponding to an image obtained by averaging a plurality of other frame images generated based on the probability distribution of brightness for each pixel,
wherein the measurements in (A) and (B) are performed based on the image of the substrate generated in (c).

11. The method of claim 10, wherein the probability distribution of brightness follows at least one of a lognormal distribution or a sum of lognormal distributions, a Weibull distribution, and a gamma-Poisson distribution, or a combination thereof.

12. The method of claim 10, wherein the probability distribution of brightness follows a lognormal distribution, two parameters μ and σ that determine the lognormal distribution are calculated for each pixel in (b), and the image of the substrate is generated based on the two parameters μ and σ in (c).

13. The method of claim 10, wherein in (c), the plurality of other frame images are sequentially generated based on the probability distribution of brightness for each pixel, and the image of the substrate is generated by averaging the plurality of other frame images thus sequentially generated.

14. The method of claim 13, wherein a plurality of images of the substrate is generated in (c),
(A) includes calculating edge coordinates of the pattern based on each of the plurality of images of the substrate to acquire a statistic amount of the edge coordinates of the pattern based on a result of the calculation, and measuring a pitch of the pattern based on the acquired statistic amount of the edge coordinates of the pattern, and
the other feature amounts of the pattern are measured in (B) based on the acquired statistic amount of the edge coordinates of the pattern, the measurement result of the pitch obtained in (A), and the design value of the pitch.

15. The method of claim 10, wherein the plurality of other frame images are images in which the brightness of each pixel is set as a random value generated based on the probability distribution of brightness for each pixel.

16. The method of claim 10, wherein in (c), an image in which the brightness of each pixel is set as an expected value of the probability distribution of brightness is generated as the image of the substrate.

17. The method of claim 1, wherein the other feature amounts of the pattern includes at least one of a line width of the pattern, a line width roughness of the pattern, and a line edge roughness of the pattern.

18. The method of claim 1, further comprising:
analyzing the pattern based on the result of the scanning, the measurement result of the pitch obtained in (A), and the design value of the pitch.

19. A feature amount measurement device for measuring a feature amount of a pattern formed on a substrate and provided with periodic irregularities, comprising:
a pitch measurement part configured to measure a pitch of the pattern based on a result of a scanning of a charged particle beam on the substrate; and
a feature amount measurement part configured to measure other feature amounts other than the pitch of the pattern based on the result of the scanning, and correct the measurement result of the other feature amounts based on a ratio of the measurement result of the pitch obtained by the pitch measurement part to a design value of the pitch.

20. The device of claim 19, further comprising:
an acquisition part configured to acquire a plurality of frame images obtained by scanning the charged particle beam on the substrate;
a probability distribution determination part configured to determine a probability distribution of brightness for each pixel from the plurality of the frame images; and
an image generation part configured to generate an image of the substrate corresponding to an image obtained by averaging a plurality of other frame images generated based on the probability distribution of brightness for each pixel,
wherein the measurements in the pitch measurement part and the feature amount measurement part are performed based on the image of the substrate generated by the image generation part.
